(19) United States
(12) Patent Application Publication
(10) Pub. No.: US 2026/0275572 A1
(43) Pub. Date: Sep. 17, 2026

(54) COMPOSITE STRUCTURE COMPRISING A MONOCRYSTALLINE THIN FILM ON A POLYCRYSTALLINE SILICON CARBIDE SUPPORT SUBSTRATE, AND ASSOCIATED MANUFACTURING METHOD

(71) Applicant: Soitec, BERNIN (FR)

(72) Inventors: Hugo Biard, BERNIN (FR); Alexandre Potier, Verneuil Sur Seine (FR); Marc Ferrato, Horgues (FR); Pablo Lefevre, Colombes (FR)

(21) Appl. No.: 18/850,748

(22) PCT Filed: Mar. 10, 2023
(86) PCT No.: PCT/EP2023/056240

§ 371 Date: Sep. 25, 2024

(30) Foreign Application Priority Data
Mar. 30, 2022 (FR) FR2202859

(51) Int. Cl. C30B 29/36; C30B 29/04; C30B 33/06

(52) U.S. Cl. CPC C30B 29/36; C30B 29/04; C30B 33/06

(57) ABSTRACT

A composite structure for manufacturing microelectronic components comprises a monocrystalline thin film disposed on a support substrate of polycrystalline silicon carbide, the support substrate having a preferred crystalline orientation, in which:
a C422 texture coefficient is less than 30%; and
a C220 texture coefficient is greater than 60% or the sum of the C111+C222+C511 texture coefficients is greater than 70%.

A method is used for manufacturing such a composite structure.

### CROSS-REFERENCE TO RELATED APPLICATIONS

This application is a national phase entry under 35 U.S.C. § 371 of International Patent Application PCT/EP2023/056240, filed Mar. 10, 2023, designating the United States of America and published as International Patent Publication WO 2023/186498 A1 on Oct. 5, 2023, which claims the benefit under Article 8 of the Patent Cooperation Treaty of French Patent Application Serial No. FR2202859, filed Mar. 30, 2022.

### TECHNICAL FIELD

The present disclosure relates to the field of semiconductor materials for microelectronic components. The present disclosure particularly relates to a composite structure comprising a thin single-crystal layer disposed on a support substrate made of polycrystalline silicon carbide. The thin single-crystal layer is preferably made of silicon carbide, and the composite structure is intended for power electronics applications.

### BACKGROUND

SiC is increasingly widely used for manufacturing innovative power devices, to meet the requirements of growing fields of application of electronics, such as electric vehicles, in particular. Indeed, power devices and integrated power-supply systems based on single-crystal silicon carbide are able to handle a much higher power density than their conventional silicon equivalents, and to do so with smaller active regions.

Nevertheless, high-quality single-crystal SiC (c-SiC) substrates intended for the microelectronics industry remain expensive and difficult to supply in large sizes. It is thus advantageous for layer transfer solutions to be used to produce composite structures typically comprising a thin layer made of single-crystal SiC (obtained from the high-quality c-SiC substrate) on a lower cost support substrate, for example, made of polycrystalline SiC (p-SiC). The electronic components then can be produced on and/or in the thin layer.

A well-known thin layer transfer solution is the SMART CUT™ method, which is based on light ion implantation and direct bonding assembly between a single-crystal donor substrate and a support substrate on a bonding interface.

Currently, p-SiC substrates are available on the market that can be used as support substrates. However, their mechanical, electrical and even thermal characteristics are not necessarily optimal for obtaining a high-quality composite structure from a thin layer transfer method intended for power applications.

As mentioned above, power electronics applications require excellent vertical electrical conduction in the composite structure. The thin single-crystal layer thus can be doped, depending on the requirements of the application. For example, to have N-type doping and resistivity that is less than or equal to 30 mOhm·cm, 10 mOhm·cm, or even less than 1 mOhm·cm.

However, ensuring good electrical conductivity in the support substrate of the composite structure is also required. To this end, the polycrystalline substrate is usually heavily doped (in particular, N-type doping), in order to achieve resistivity of less than 30 mOhm·cm. Furthermore, the assembly interface of the composite structure must be designed in such a way that the vertical electrical resistance is not (or is only slightly) increased.

However, other applications exist that do not require vertical electrical conduction, but instead aim for high resistivity of the support substrate. This is particularly the case for radio frequency applications. The other features of the support substrate listed hereafter (mechanical and even thermal) are required for these RF applications, as well as for the power applications.

A thin layer transfer method, based on direct molecular adhesion bonding, is highly dependent on the surface quality of the assembled substrates. In particular, a roughness that is less than or equal to 1 nm RMS (root mean square roughness) is required, combined with very low surface defectiveness (particles, holes, etc. or other reliefs likely to generate bonding defects), both for the support substrate and for the donor substrate.

The hardness of SiC and the presence of grains on the surface of the single-crystal support substrate make surface preparation very complex and perfect quality proves to be difficult to achieve.

Finally, it is essential for support substrates to be used that exhibit low curvature or deformation. Curvature corresponds to the deflection or “warp,” which is equivalent to the algebraic difference of the deviations of the substrate relative to a reference plane. Low curvature is required, on the one hand, so that these support substrates are compatible with good quality direct assembly and high bonding energy, and, on the other hand, so that they are not likely to cause damages in the thin single-crystal layer during or after the transfer method, due to high mechanical stresses. Low curvature is also important to ensure the performance capabilities of the manufacturing steps (for example, photolithography) of the components on/in the thin layer of the composite structure. The curvature radius (proportional to the inverse of the warp) of p-SiC support substrates is typically intended to be greater than approximately 25 m, that is, a curvature (“warp”) that is less than or equal to 100 micrometers (micrometers will be referred to as “microns” throughout the remainder of the document for the sake of simplicity) for a 150 mm diameter substrate, for example.

In addition, it is often important that the support substrate guarantees good thermal conductivity, in order to efficiently discharge the heat, which is particularly generated by power components.

All these specifications are very complex to achieve with p-SiC substrates.

U.S. Pat. No. 10,934,634 proposes a p-SiC substrate for which the rate of change of the grain size between the two faces of the substrate is less than 0.43%, yielding a curvature radius of more than 142 m. Furthermore, at least one face of the substrate exhibits arithmetic average roughness of less than 1 nm.

However, this method remains expensive and highly energy and material intensive, since a significant portion of the p-SiC initially deposited onto a graphite substrate is removed and lost in order to obtain the proposed p-SiC substrate (typically 2 mm initially deposited in order to form a 350 micron p-SiC substrate).

### BRIEF SUMMARY

The present disclosure proposes a composite structure comprising a thin layer made of single-crystal material, in particular, of c-SiC, disposed on a p-SiC support substrate. The present disclosure also relates to a method for manufacturing such a composite structure.

The present disclosure relates to a composite structure for manufacturing microelectronic components comprising a thin single-crystal layer disposed on a support substrate made of polycrystalline silicon carbide, the support substrate having a preferred crystalline orientation, in which:
a C₄₂₂ texture coefficient is less than 30%, in particular, less than 20%; and
a C₂₂₀ texture coefficient is greater than 60% or the sum of the C₁₁₁+C₂₂₂+C₅₁₁ texture coefficients is greater than 70%, in particular, greater than 80%.

According to other advantageous and non-limiting features of the present disclosure, taken alone or according to any technically feasible combination:
the support substrate has nitrogen doping and resistivity of less than 30 mOhm·cm;
the thin layer is composed of silicon carbide;
the thin layer is composed of diamond;
the composite structure comprises a continuous or discontinuous intermediate layer, disposed between the thin layer and the support substrate and composed of at least one metallic or semiconductor material;
the intermediate layer is composed of silicon, silicon carbide, tungsten, and/or titanium;
the C₄₂₂ texture coefficient is less than 15%, even less than 10%;
the thickness of the support substrate ranges between 50 microns and 800 microns, preferably between 60 microns and 500 microns.
the composite structure comprises an electronic component on and/or in the thin layer and optionally comprises an electrical contact on the rear face of the support substrate.

The present disclosure also relates to a method for manufacturing a composite structure comprising a thin single-crystal layer disposed on a support substrate made of polycrystalline silicon carbide, the manufacturing method comprising the following steps:
a) providing a support substrate made of polycrystalline silicon carbide having a preferred crystalline orientation, in which:
   a C₄₂₂ texture coefficient is less than 30%, in particular, less than 20%; and
   a C₂₂₀ texture coefficient is greater than 60% or the sum of the C₁₁₁+C₂₂₂+C₅₁₁ texture coefficients is greater than 70%, in particular, greater than 80%;
b) providing a donor substrate made of a single-crystal material; and
c) transferring a thin layer originating from the donor substrate onto the support substrate.

According to other advantageous and non-limiting features of the present disclosure, taken alone or according to any technically feasible combination:
the transfer step c) comprises:
   c1) forming a weak embedded plane in the donor substrate, delimiting the thin layer between the weak embedded plane and a front face of the donor substrate;
   c2) assembling the donor substrate on the support substrate by molecular adhesion bonding, directly or via an intermediate layer;
   c3) separating along the weak embedded plane in order to result in the transfer of the thin layer onto the support substrate;
the step c2) comprises, before assembling the two substrates:
   forming an intermediate layer on the donor substrate, before or after step c1); and/or
   forming an intermediate layer on the support substrate,
the intermediate layer (30) being formed by at least one metallic or semiconductor material selected from among silicon, silicon carbide, tungsten and titanium;
the single-crystal material forming the donor substrate is silicon carbide;
the manufacturing method further comprises producing electronic components on and/or in the thin layer of the composite structure;
the production of electronic components particularly comprises a homoepitaxy or heteroepitaxy step on the thin layer.

### BRIEF DESCRIPTION OF THE DRAWINGS

Further features and advantages of the present disclosure will become apparent from the following detailed description of example embodiments of the present disclosure, which is provided with reference to the appended figures, in which:

FIG. 1 shows a composite substrate according to the present disclosure;

FIG. 2 shows a table listing the 10 diffraction peaks, classified by increasing Miller indices (hkl), considered in a 3C polytype SiC substrate and measurable by X-ray diffraction; the table also shows the position of the peaks and their theoretical intensity;

FIGS. 3A-3C show micrographs (SEM) of support substrates, produced under different conditions and with different preferred crystalline orientations or textures, implemented in order to manufacture composite structures according to the present disclosure;

FIG. 4 shows a composite substrate according to the present disclosure;

FIGS. 5A-5D show steps of a manufacturing method according to the present disclosure;

FIG. 6 shows production conditions and the associated features of five samples of support substrates, with the samples 2, 3 and 4 being suitable for composite structures according to the present disclosure.

The same reference signs in the figures can be used for elements of the same type. Some figures are schematic representations that, for the purpose of legibility, are not to scale. In particular, the thicknesses of the layers along the z-axis are not to scale relative to the lateral dimensions along the x- and y-axes; and the relative mutual thicknesses of the layers are not necessarily adhered to in the figures.

### DETAILED DESCRIPTION

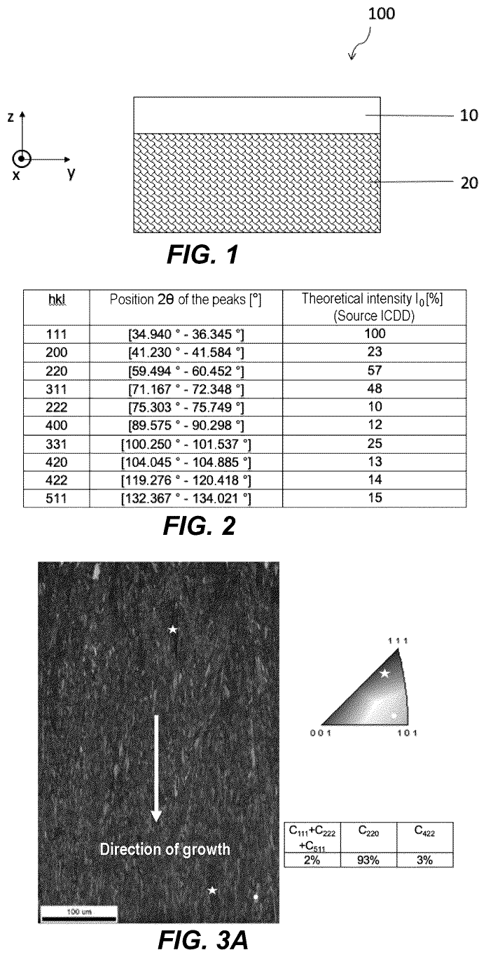

The present disclosure relates to a composite structure 100 particularly suitable for manufacturing microelectronic components comprising a thin single-crystal layer 10, in particular, made of silicon carbide, diamond, silicon, II-VI or III-V semiconductor compounds (for example, AlN, GaN, etc.), or even of gallium oxide (Ga₂O₃), disposed on a support substrate 20 made of polycrystalline silicon carbide (FIG. 1).

In a main plane (x, y), the composite structure 100 is preferably in the form of a circular wafer with a diameter of 100 mm, 150 mm, 200 mm, or even more. However, it also could be in any other form allowing it to be subsequently processed for manufacturing components. The thickness of the composite structure 100 extends along the z-axis in the figures.

The thickness of the thin layer 10 of the composite structure 100 typically ranges between a few tens of nm and a few hundred nm, for example, between 50 nm and 800 nm. It will be seen hereafter that epitaxy steps can be implemented on the thin layer 10, in order to thicken it (homoepitaxy) or to grow other materials (heteroepitaxy), for the requirements of the electronic components to be manufactured.

The thin layer 10 exhibits electrical resistivity that is adapted to the application and to the targeted components. For example, for power components, its resistivity is usually less than 30 mOhm·cm, 10 mOhm·cm, or even 1 mOhm·cm, with N-type doping (nitrogen dopant). For RF components, its resistivity can be greater than 100 Ohm·cm, or even 10 kOhm·cm, without specific doping or with the addition of vanadium, for example.

The support substrate 20, as its name indicates, corresponds to the mechanical support of the composite structure 100. The lateral dimensions in the main plane (x, y) of the support substrate 20 (its diameter, in particular) are the same as those of the composite structure 100. It should be noted that the thin layer 10 can have a slightly smaller lateral dimension, due to the transfer method: indeed, a peripheral ring of the support substrate 20 is usually devoid of a thin layer 10 because the edge flange or the chamfer of the substrate 20 prevents the assembly and the effective application of the layer 10.

In the composite structure 100, the thickness of the support substrate 20 typically ranges between several hundred microns and approximately 50 microns, for example, between 800 microns and 50 microns, in particular, between 500 microns and 60 microns, or even between 350 microns and 100 microns.

When good vertical electrical conductivity is required (power applications), the support substrate 20 has electrical resistivity of less than 30 mOhm·cm, 15 mOhm·cm or even less than 10 mOhm·cm. When the thin layer 10 is of the N-type, the type of doping of the support substrate 20 is usually selected so as to be the same, i.e., typical nitrogen doping. In order to achieve the aforementioned low resistivity, the nitrogen concentration (which can be measured by secondary ion mass spectroscopy) is generally greater than 5E19 atoms/cm³, preferably greater than or equal to 1E20 atoms/cm³, or even greater than or equal to 1.5E20 atoms/cm³.

When high resistivity is intended for the support substrate (greater than 100 Ohm·cm, or even greater than 10 kOhm·cm, or even greater), the p-SiC support substrate 20 is produced from very pure precursors (for example, methyltrichlorosilane) and/or with the addition of impurities such as vanadium.

The support substrate 20, made of 3C polytype p-SiC, also has a preferred crystalline orientation. The preferred crystalline orientation is characterized in this case with particular proportions of various texture coefficients.

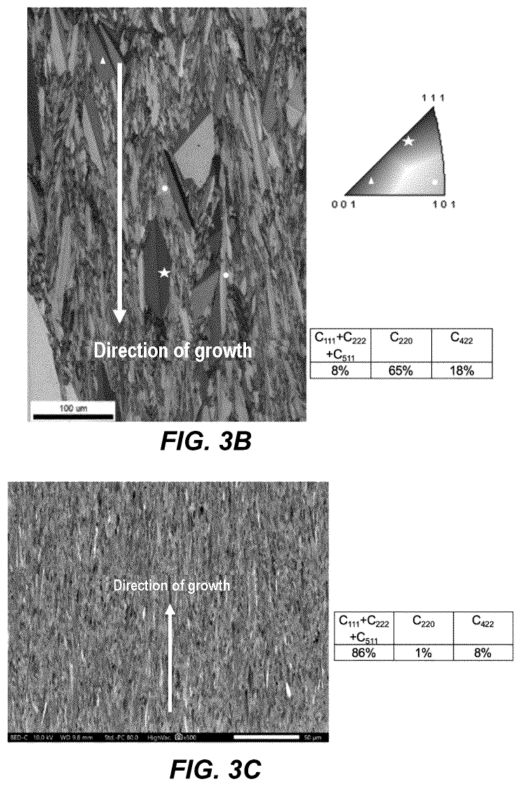

A texture coefficient can be expressed as a percentage and quantifies the preferred average orientation of the crystallites of the support substrate 20 relative to the normal to the surface of the substrate 20. By way of a reminder, the texture coefficients can be measured by virtue of the method described by G. Harris (“X. Quantitative measurement of preferred orientation in rolled uranium bars,” Philosophical Magazine Series 7, 43:336, 113-123, 1952). In practice, they are measured from the diffraction peaks gathered by an X-ray diffractometer, using the θ-2θ method over an angle range ranging from 10° to 135° (20 scale). Over this range, the ten diffraction peaks listed in the table (shown in FIG. 2) and classified according to increasing Miller indices (hkl), can be taken into account in a 3C polytype SiC substrate.

A texture coefficient Cₕₖₗ is computed on the basis of the peak intensity Iₕₖₗ, which is proportional to the area under the peak of the sample, and of the theoretical intensity I_{0 hkl} of a powder, which can be acquired on the basis of the theoretical percentages published by the ICDD (International Centre for Diffraction Data). A texture coefficient Cₕₖₗ is expressed as follows:

Cₕₖₗ=(Iₕₖₗ/I_{0 hkl})/(1/N×Σ(Iₕₖₗ/I_{0 hkl})), with N being the number of peaks taken into account.

According to a first alternative embodiment, the preferred crystalline orientation of the support substrate 20 is characterized by a C₄₂₂ texture coefficient of less than 30% and a C₂₂₀ texture coefficient of more than 60%.

According to a second alternative embodiment, the preferred crystalline orientation of the support substrate 20 is characterized by a C₄₂₂ texture coefficient of less than 30% and the fact that the sum of the C₁₁₁+C₂₂₂+C₅₁₁ texture coefficients is greater than 70%.

Preferably, for either of the stated alternative embodiments, the C₄₂₂ texture coefficient is less than 20%, less than 15%, or even less than 10%.

Preferably, according to the second alternative embodiment, the sum of the C₁₁₁+C₂₂₂+C₅₁₁ texture coefficients is greater than 80%.

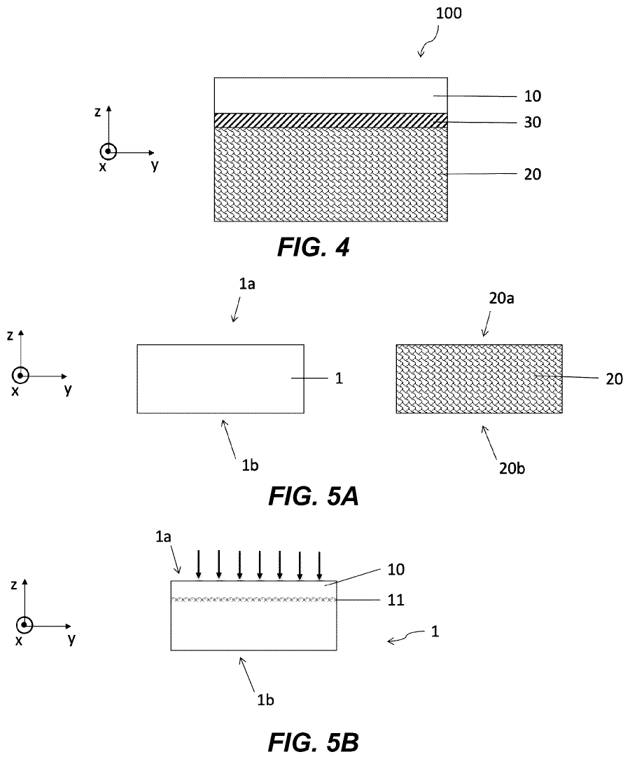

FIGS. 3A-3C show three examples of textures of support substrates 20 for a composite structure 100 according to the present disclosure. The images are acquired by scanning electron microscopy (SEM) by backscattered electrons (EBSD) in the transverse plane (y, z), i.e., in a cross-section (section) of the support substrate 20. On the right of FIGS. 3A and 3B, a texture triangle includes, by way of information, certain facets marked with various white symbols; the symbols are also applied to certain textures of the SEM images, by way of illustration. The percentages of the main texture coefficients of interest are shown to the right of the SEM images in FIGS. 3A-3C.

The preferred textures (according to the two aforementioned alternative embodiments), combined with the high doping (when vertical electrical conduction is required), allow a support substrate 20 to be acquired that meets the physical, mechanical and electrical specifications expected in the composite structure 100, namely:
excellent flatness (low curvature);
low electrical resistivity (when required for the application and the components to be manufactured on the composite structure 100); and
good thermal conductivity (particularly in the case of the first stated alternative embodiment).

The curvature radius of the support substrate 20 is greater than 25 m, advantageously greater than or equal to 50 m. By way of an example, a 150 mm diameter support substrate 20 has a curvature (or “warp”) that is less than or equal to 100 microns, or even 50 microns, and a 200 mm diameter support substrate 20 has a curvature (or “warp”) that is less than or equal to 150 microns, or even 70 microns.

The range of the curvature radius of the support substrate 20 makes the substrate perfectly compatible with the specifications of a composite structure 100 provided with a thin single-crystal layer 10, with the method for manufacturing such a structure 100 and with the subsequent production of microelectronic components on and/or in the thin layer 10. It should be noted that the curvature of the composite structure 100 remains close to the curvature of the support substrate 20.

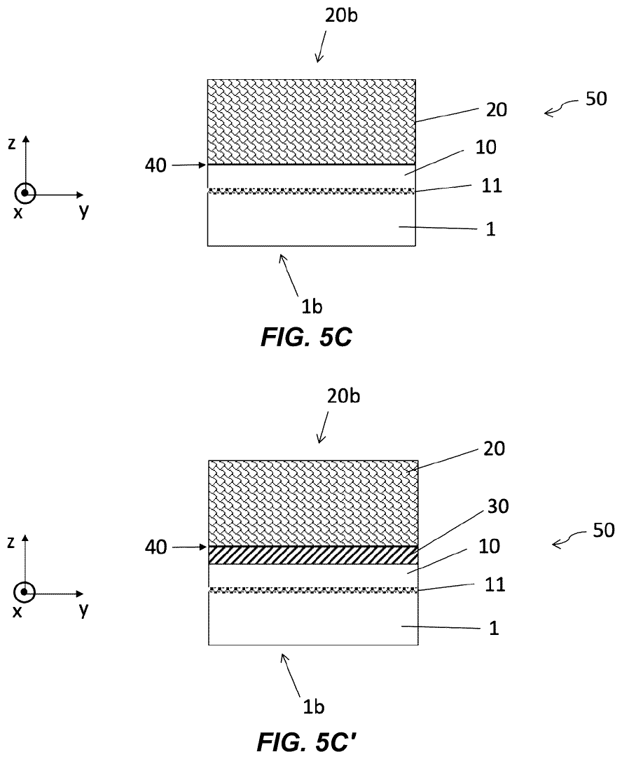

According to a particular embodiment of the present disclosure, the composite structure 100 comprises a continuous or discontinuous intermediate layer 30, disposed between the thin layer 10 and the support substrate 20 and composed of at least one metallic or semiconductor material (FIG. 4). As will be described below, with reference to a method for manufacturing the composite structure 100, the intermediate layer 30 can be formed on the side of the thin layer 10, on the side of the support substrate 20, or on both sides, prior to assembly along a bonding interface 40.

The intermediate layer 30 can be composed of silicon, silicon carbide, tungsten and/or titanium, for example. It typically ranges between a few nm and a few hundred nm thick, preferably between 2 nm and 50 nm.

The present disclosure also relates to a method for manufacturing the composite structure 100.

The method comprises a first step a) of providing a support substrate 20 made of polycrystalline silicon carbide having a preferred crystalline orientation, in which:
a C₄₂₂ texture coefficient is less than 30%, in particular, less than 20%, less than 15% or even less than 10%; and
a C₂₂₀ texture coefficient is greater than 60% or the sum of the C₁₁₁+C₂₂₂+C₅₁₁ texture coefficients is greater than 70%, in particular, greater than 80%.

Preferably, in order to address power electronics applications, the support substrate 20 has nitrogen doping allowing electrical resistivity of less than 30 mOhm·cm, 15 mOhm·cm, or even less than 10 mOhm·cm, to be achieved.

The curvature radius of the support substrate 20 is greater than 25 m, advantageously greater than or equal to 50 m.

Step a) implements a Chemical Vapor Deposition (CVD) technique. This technique involves a gas mixture comprising at least one silicon precursor gas (such as a silane or a chlorosilane) and/or at least one carbon precursor gas (such as an alkane or an alkene), and/or at least one silicon and carbon precursor gas (such as methyltrichlorosilane, abbreviated to MTCS), and, if necessary, at least one doping gas comprising nitrogen (for example, NH₃, N₂H₄, N₂). The doping gas also can be a carbon and/or silicon precursor (for example, an amine such as H₂NCH₃). These gases can be diluted in a carrier gas, which can be a reducing gas such as hydrogen and/or an inert gas such as argon.

This gas mixture is admitted into a reactor at high temperature where the precursor gases are decomposed and react on the surface of a seed, preferably made of fine-grained and purified isostatic graphite, in order to form the 3C-SiC polytype, for which the mechanical and thermal resistance properties, the coefficient of thermal expansion and the purity are perfectly compatible with the specifications of the composite structure 100. Moreover, the 3C—SiC polytype can be doped with nitrogen up to very high levels, typically 10²⁰ atoms/cm³, and thus exhibit resistivity of less than 30 mOhm·cm, without degrading the quality of the substrate, which would be detrimental to the quality of the composite structure and subsequently to the performance capabilities of the microelectronic components. Finally, it is a material capable of withstanding the high temperature methods that the support substrate 20 will have to undergo when manufacturing the composite structure 100 and the components.

The reactor temperature during the CVD deposition of SiC should be between approximately 1,000° C. and approximately 1,600° C., preferably between approximately 1,100° C. and approximately 1,400° C. Within this temperature range, the deposition rates can vary over fairly wide ranges, from a micron/hr to over 100 micron/hr. Advantageously, the total pressure in the reactor does not exceed 350 mbar or even 300 mbar.

By modifying the parameters of the CVD method, such as the temperature, the partial pressure of the precursor and potentially the percentage of doping gas, the crystalline orientation/texture of the deposited p-SiC layer can be changed.

After deposition, the graphite seeds coated with a thick SiC deposition layer are machined and then oxidized in air, typically at 900° C., in order to remove any graphite residue. It should be noted that the removal of the graphite seeds also can be carried out by mechanical machining techniques only or even basically by burning/oxidation.

A raw p-SiC wafer is recovered for each face of a seed. The raw p-SiC wafer exhibits a curvature due to the relief of the stresses of the deposited layer. This curvature can be measured using a confocal white light sensor that scans a surface of the p-SiC wafer.

The raw p-SiC wafer is then thinned by coarse and then fine grinding, and undergoes surface preparation by polishing in order to arrive at the p-SiC support substrate 20 with the key features set forth above when describing the composite structure 100. In particular, the aim of the grinding step is to remove enough thickness from the side of the face of the wafer that was in contact with the graphite. This removes the initial crystal growth area, which generates significant stresses.

It is important that the curvature of the raw p-SiC wafer remains within a reasonable range in order to allow the production of a low-curvature support substrate 20 from a raw wafer with an economically viable thickness. For example, the curvature (“warp”) of a raw p-SiC wafer with a diameter of 150 mm and a thickness of less than 900 microns is targeted so as to be less than or equal to 250 microns. It is thus possible, after grinding and polishing, to acquire a support substrate 20 with a thickness that is typically less than 500 microns and with a curvature (“warp”) that is less than 100 microns, or less than 50 microns, or even less than 30 microns.

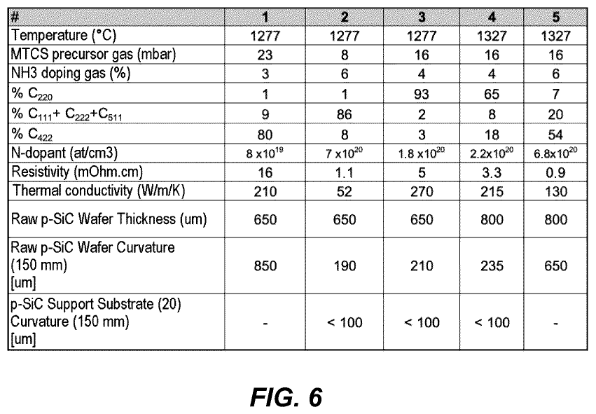

FIG. 6 shows a table with various p-SiC deposition conditions (temperature, precursor gas, pressure, mole fraction of doping gas) and the mechanical, electrical and thermal properties that are acquired. Samples 2, 3 and 4 represent the support substrates 20 for a composite structure 100 according to the present disclosure; their textures are illustrated in FIGS. 3C, 3A, and 3B, respectively.

Samples 1 and 5 do not allow the required specifications (resistivity, curvature) to be achieved for manufacturing a high quality composite structure 100 and therefore do not fall within the scope of the present disclosure. The textures of these samples are not conducive to low curvature and the size of the grains on the surface 20a, which is larger and more heterogeneous than for samples 2, 3 and 4, makes it more difficult to prepare the surface and to obtain the surface finish required for direct assembly.

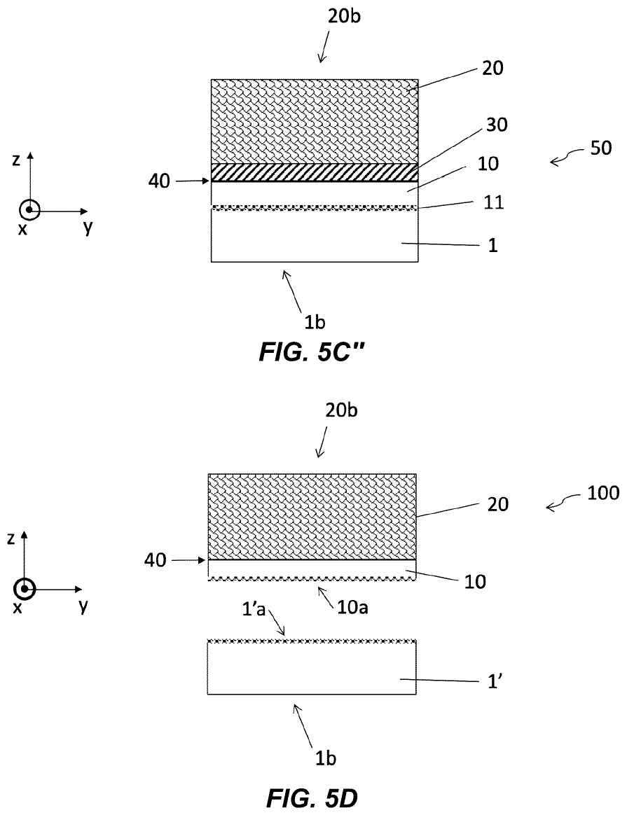

The face 20a of the support substrate 20 (FIG. 5A) intended to receive the thin layer 10 preferably exhibits roughness that is less than or equal to 1 nm RMS (measured by atomic force microscopy on 20 micron×20 micron scans), and even more preferably is less than or equal to 0.5 nm RMS. The face of the support substrate 20 intended to form the rear face of the composite structure 100 can exhibit higher surface roughness, for example, of the order of 10 nm RMS.

Step a) of the method optionally can include a heat treatment applied to the support substrate 20, at a temperature that is greater than or equal to 1,500° C., typically between 1,500° C. and 2,000° C., so as to stabilize its polycrystalline structure. Indeed, these temperature ranges are likely to be applied at a later stage in the method for manufacturing the composite structure 100.

The manufacturing method according to the present disclosure then comprises a step b) of providing a donor substrate 1 made of a single-crystal material, from which the thin layer 10 will be derived (FIG. 5A). As mentioned above with reference to the composite structure 100, the single-crystal material can be 4H, 6H or 3C polytype silicon carbide, diamond, silicon, II-IV or III-V semiconductor compounds (in particular, GaN), etc. The donor substrate 1 is preferably in the form of a wafer with a diameter of 100 mm, 150 mm, 200 mm or even more (identical to or very close to that of the support substrate 20) and with a thickness typically ranging between 300 microns and 800 microns. It has a front face 1a and a rear face 1b. The surface roughness of the front face 1a is advantageously selected so as to be less than 1 nm RMS, or even less than 0.5 nm RMS, measured by atomic force microscopy (AFM) on a 20 micron×20 micron scan. The type of doping and the resistivity of the donor substrate 1 are defined as a function of the requirements of the components that will be produced on and/or in the thin layer 10 of the composite structure 100.

Finally, the method comprises a step c) of transferring a thin layer 10 originating from the donor substrate 1 onto the support substrate 20. There are various options, which are known from the prior art, for transferring a layer (mechanical, chemical or mechano-chemical thinning, separation on a porous layer present in the donor substrate 1, etc.), which will not be exhaustively described herein.

According to a preferred embodiment, step c) of the method involves implanting light entities and assembly by direct bonding, according to the principle of the SMART CUT™ method.

A first step c1) corresponds to the introduction of light entities into the donor substrate 1 in order to form a weak embedded plane 11 delimiting, with a front face 1a of the donor substrate 1, the thin layer 10 to be transferred (FIG. 5B). It should be noted that although the thin layer 10 to be transferred is shown as a continuous layer, it also could be made up of discontinuous blocks, for example, prepared on the surface of the donor substrate 1.

The light entities are preferably hydrogen, helium or a co-implantation of these two entities, and are implanted at a determined depth in the donor substrate 1, consistent with the targeted thickness of the thin layer 10. These light entities will form, around the determined depth, microcavities distributed in a fine layer parallel to the front face 1a of the donor substrate 1, that is parallel to the plane (x, y) in the figures. This fine layer is referred to as the weak embedded plane 11, for the sake of simplicity.

The implantation energy of the light entities is chosen so as to reach the determined depth. For example, hydrogen ions will be implanted with an energy level ranging between 10 keV and 250 keV, and at a dose ranging between 5^{E}16/cm² and 1^{E}17/cm², in order to delimit a thin layer 10 with a thickness of approximately 100 nm to 1,500 nm. It should be noted that a protective layer can be deposited onto the front face 1a of the donor substrate 1 prior to the ion implantation step. This protective layer can be composed of a material such as silicon oxide or silicon nitride, for example. It is removed prior to the following phase.

The transfer step c) then comprises a second phase c2) of assembling the donor substrate 1, on the side of its front face 1a, on the support substrate 20, on the side of its first face 20a, by molecular adhesion bonding, along a bonding interface 40 (FIG. 5C).

Optionally, an intermediate layer 30 can be formed on the front face 1a of the donor substrate 1, before or after the phase c1) of introducing the light entities, and, in any case, before the assembly phase. This intermediate layer 30 can be made of a semiconductor material, for example, silicon or silicon carbide, or of a metallic material, such as tungsten, titanium, etc. The thickness of the intermediate layer 30 is advantageously limited, typically to between a few nanometers and a few tens of nanometers.

In the case whereby the intermediate layer 30 is formed before the first phase c1), the implantation energy (and potentially the dose) of the light entities will be adjusted at the crossover of this additional layer. In the case whereby the intermediate layer 30 is formed after the phase c1), care will be taken to form this layer by applying a thermal budget lower than the bubbling thermal budget, with the bubbling thermal budget corresponding to the appearance of blisters on the surface of the donor substrate 1 due to excessively high growth and pressurization of the microcavities in the weak embedded plane 11.

Optionally, an intermediate layer 30 also can be deposited onto the face of the support substrate 20 that is to be assembled, prior to the assembly phase; it can be selected so as to be the same nature as or a different nature from the intermediate layer 30 mentioned for the donor substrate 1. An intermediate layer 30 optionally can be deposited onto either one of the two substrates 1, 10 to be assembled.

The purpose of the one or more intermediate layer(s) is basically to promote the bonding energy (especially in the range of temperatures below 1,100° C.), due to the formation of covalent bonds at lower temperatures than in the case of two directly assembled SiC surfaces; another advantage of this (these) intermediate layer(s) can be to improve the vertical electrical conduction of the bonding interface 40.

The one or more intermediate layer(s) 30 is(are) intended to be embedded in the bonded assembly 50 after assembly (FIGS. 5C′, 5C″), and ultimately in the composite structure 100. Even if the intermediate layer 30 is continuous when formed on one and/or other of the substrates 1, 20, it can, during subsequent heat treatments, be segmented and have a discontinuous nature. This is basically the case when the initial thickness of the layer is very low, typically less than 10 nm.

With further reference to the description of assembly phase c2), and as is well known per se, direct molecular adhesion bonding does not require an adhesive material, since bonds are established at the atomic level between the assembled surfaces. Several types of molecular adhesion bonding exist, which particularly differ in terms of their temperature conditions, pressure conditions, atmosphere conditions, or the treatments prior to bringing the surfaces into contact. Room temperature bonding with or without prior plasma activation of the surfaces to be assembled, atomic diffusion bonding (ADB), surface-activated bonding (SAB), etc., can be cited.

The assembly phase c2) can include, prior to bringing the faces 1a, 20a to be assembled into contact, conventional sequences of chemical cleaning (for example, RCA cleaning), of surface activation (for example, by oxygen or nitrogen plasma) or other surface preparations (such as cleaning by brushing (scrubbing)), which are liable to promote the quality of the bonding interface 40 (low defectiveness, high adhesion energy).

Finally, a third phase c3) includes separation along the weak embedded plane 11, which leads to the thin layer 10 being applied onto the support substrate 20 (FIG. 5D).

Separation along the weak embedded plane 11 is usually carried out by applying a heat treatment at a temperature ranging between 800° C. and 1,200° C. Such a heat treatment causes cavities and micro-cracks to develop in the weak embedded plane 11, and causes them to be pressurized by the light entities present in gaseous form, until a fracture propagates along the weak plane 11. Alternatively, or conjointly, a mechanical stress can be applied to the bonded assembly, and, in particular, to the weak embedded plane 11, so as to propagate or assist the mechanical propagation of the fracture leading to the separation. On completion of this separation, the composite structure 100 comprising the support substrate 20 and the transferred thin layer 10 are obtained, on the one hand, and the remainder 1′ of the donor substrate is obtained, on the other hand. The level and the type of doping of the thin layer 10 are defined by the selection of the properties of the donor substrate 1 or can be subsequently adjusted via the known techniques for doping semiconductor layers.

The free surface 10a of the thin layer 10 is usually rough after separation: for example, it exhibits a roughness ranging between 5 nm and 100 nm RMS. Cleaning and/or smoothing phases can be applied in order to restore a good surface finish (typically, a roughness of less than a few angstroms RMS). In particular, these phases can include a mechano-chemical smoothing treatment of the free surface of the thin layer 10. Removal of between 50 nm and 300 nm allows the surface finish of the layer 10 to be effectively restored. The phases can also include at least one heat treatment at a temperature ranging between 1,200° C. and 1,800° C. Such a heat treatment is applied to remove the residual light entities from the thin layer 10 and to promote the rearrangement of the crystal lattice of the thin layer 10. It also allows the bonding interface 40 to be strengthened. The heat treatment can also include or correspond to epitaxy on the thin layer 10, in order to increase the thickness thereof (for example, homoepitaxy of c-SiC on a c-SiC thin layer 10, heteroepitaxy of GaN on a c-SiC thin layer 10, or the like).

Finally, it should be noted that the transfer step c) can include a step of reconditioning the remainder 1′ of the donor substrate with a view to reuse as the donor substrate 1 for a new composite structure 100. Mechanical and/or chemical treatments, similar to those applied to the composite structure 100, can be implemented on the front face 1′a of the remaining substrate 1′.

The composite structure 100 that is obtained is extremely robust with respect to the very high temperature heat treatments that can be applied to improve the quality of the thin layer 10 or to manufacture components on and/or in the layer 10. The support substrate 20 in the composite structure 100 is stable and its curvature does not prohibitively increase during the high temperature heat treatments applied to the composite structure 100 for the manufacturing thereof and thereafter.

The composite structure 100 according to the present disclosure is particularly suitable for producing one (or more) high-voltage microelectronic component(s), such as, for example, Schottky diodes, MOSFET transistors, etc. More generally, it is suitable for power microelectronic applications, allowing excellent vertical electrical conduction, good thermal conductivity and providing a high-quality c-SiC thin layer.

The composite structure 100 also can be suitable for radio frequency applications, with a resistive support substrate 20, the physical and potentially thermal characteristics of which are perfectly suited to manufacturing RF electronic components.

Of course, the present disclosure is not limited to the embodiments and to the examples that have been described, and alternative embodiments can be added thereto without departing from the scope of the invention as defined by the claims.

1. A composite structure for manufacturing microelectronic components, comprising a thin single-crystal layer disposed on a support substrate of polycrystalline silicon carbide, the support substrate having a crystalline orientation, in which:
a C₄₂₂ texture coefficient is less than 30%; and
a C₂₂₀ texture coefficient is greater than 60% or the sum of the C₁₁₁+C₂₂₂+C₅₁₁ texture coefficients is greater than 70%.

2. The composite substrate of claim 1, wherein the support substrate has nitrogen doping and resistivity of less than 30 mOhm·cm.

3. The composite substrate of claim 1, wherein the thin layer is composed of silicon carbide.

4. The composite substrate of claim 1, wherein the thin layer is composed of diamond.

5. The composite substrate of claim 1, further comprising a continuous or discontinuous intermediate layer disposed between the thin layer and the support substrate, and the intermediate layer composed of at least one metallic or semiconductor material.

6. The composite substrate of claim 5, wherein the intermediate layer is composed of silicon, silicon carbide, tungsten, and/or titanium.

7. The composite substrate of claim 1, wherein the C₄₂₂ texture coefficient is less than 15%.

8. The composite substrate of claim 1, wherein the thickness of the support substrate ranges between 50 microns and 800 microns.

9. The composite substrate of claim 1, further comprising an electronic component on and/or in the thin layer.

10. A method for manufacturing a composite structure comprising a thin single-crystal layer disposed on a support substrate of polycrystalline silicon carbide, the method comprising the following steps:
a) providing a support substrate of polycrystalline silicon carbide having a crystalline orientation, in which:
a C₄₂₂ texture coefficient is less than 30%; and
a C₂₂₀ texture coefficient is greater than 60% or the sum of the C₁₁₁+C₂₂₂+C₅₁₁ texture coefficients is greater than 70%;
b) providing a donor substrate of a single-crystal material; and
c) transferring a thin layer originating from the donor substrate onto the support substrate.

11. The method of claim 10, wherein the transfer step c) comprises the following sub steps:
c1) forming a weak embedded plane in the donor substrate, delimiting the thin layer between the weak embedded plane and a front face of the donor substrate;
c2) assembling the donor substrate on the support substrate by molecular adhesion bonding, directly or via an intermediate layer; and
c3) separating along the weak embedded plane to result in the transfer of the thin layer onto the support substrate.

12. The method of claim 11, wherein the sub step c2) comprises, before assembling the two substrates:
forming an intermediate layer on the donor substrate, before or after step c1); and/or
forming an intermediate layer on the support substrate,
the intermediate layer being formed by at least one metallic or semiconductor material selected from among silicon, silicon carbide, tungsten and titanium.

13. The method of claim 11, wherein the single-crystal material forming the donor substrate is silicon carbide.

14. The method of claim 10, further comprising producing electronic components on and/or in the thin layer of the composite structure.

15. The method of claim 14, wherein the producing electronic components comprises a homoepitaxy or heteroepitaxy deposition on the thin layer.

16. The composite substrate of claim 1, wherein the C₄₂₂ texture coefficient is less than 20%.

17. The composite substrate of claim 1, wherein the sum of the C₁₁₁+C₂₂₂+C₅₁₁ texture coefficients is greater than 80%.

18. The composite substrate of claim 7, wherein the C₄₂₂ texture coefficient is less than 10%.

19. The composite substrate of claim 8, wherein the thickness of the support substrate ranges between 60 microns and 500 microns.

20. The composite substrate of claim 9, further comprising an electrical contact on a rear face of the support substrate.
